(19) United States
(12) Patent Application Publication
(10) Pub. No.: US 2026/0082817 A1
(43) Pub. Date: Mar. 19, 2026

(54) MAGNETIC MEMORY DEVICE

(71) Applicant: Kioxia Corporation, Tokyo (JP)

(72) Inventors: Naoki AKIYAMA, Yokkaichi Mie (JP); Kenichi YOSHINO, Seongnam-si Gyeonggi-do (KR); Hyungjun CHO, Seongnam-si Gyeonggi-do (KR); Hyung-Woo AHN, Seongnam-si Gyeonggi-do (KR); Takuya SHIMANO, Seongnam-si Gyeonggi-do (KR)

(73) Assignee: Kioxia Corporation, Tokyo (JP)

(21) Appl. No.: 19/238,873

(22) Filed: Jun. 16, 2025

(30) Foreign Application Priority Data
Sep. 17, 2024 (JP) 2024-160279

(51) Int. Cl. H10N 50/85; H10B 61/00; H10N 50/01

(52) U.S. Cl. CPC H10N 50/85; H10B 61/10; H10N 50/01

(57) ABSTRACT

According to one embodiment, a magnetic memory device includes a lower structure, a stacked structure provided on the lower structure, a boron containing layer provided along a side surface of the stacked structure, a metal oxide layer provided between the stacked structure and the boron containing layer. The stacked structure includes a structure in which a basic portion, a lower portion and an upper portion are stacked in a first direction. The basic portion includes a structure in which a first magnetic layer having a variable magnetization direction, a second magnetic layer having a fixed magnetization direction and a nonmagnetic layer between the first and second magnetic layers are stacked in the first direction.

### CROSS-REFERENCE TO RELATED APPLICATIONS

This application is based upon and claims the benefit of priority from Japanese Patent Application No. 2024-160279, filed Sep. 17, 2024, the entire contents of which are incorporated herein by reference.

### FIELD

Embodiments described herein relate generally to a magnetic memory device.

### BACKGROUND

A magnetic memory device in which a plurality of magnetoresistance effect elements are integrated on a semiconductor substrate has been proposed.

### BRIEF DESCRIPTION OF THE DRAWINGS

FIG. 1 is a cross-sectional view schematically illustrating a configuration of a magnetic memory device according to an embodiment.

FIG. 2 is a diagram schematically illustrating a relationship between patterns of a stacked structure, a boron containing layer, a metal oxide layer, and the like when viewed from a Z direction in the magnetic memory device according to the embodiment.

FIG. 3 is a cross-sectional view schematically illustrating a part of a method of manufacturing the magnetic memory device according to the embodiment.

FIG. 4 is a cross-sectional view schematically illustrating a part of the method of manufacturing the magnetic memory device according to the embodiment.

FIG. 5 is a cross-sectional view schematically illustrating a part of the method of manufacturing the magnetic memory device according to the embodiment.

FIG. 6 is a cross-sectional view schematically illustrating a part of the method of manufacturing the magnetic memory device according to the embodiment.

FIG. 7 is a perspective view schematically illustrating a configuration of an application example of the magnetic memory device according to the embodiment.

### DETAILED DESCRIPTION

In general, according to one embodiment, a magnetic memory device comprising: a lower structure; a first stacked structure provided on the lower structure; a second stacked structure provided on the lower structure and being adjacent to the first stacked structure; a first boron containing layer provided along a side surface of the first stacked structure and containing boron (B); a second boron containing layer provided along a side surface of the second stacked structure, separated from the first boron containing layer, and containing boron (B); a first metal oxide layer provided between the first stacked structure and the first boron containing layer along the side surface of the first stacked structure and containing a predetermined metal element and oxygen (O); and a second metal oxide layer provided between the second stacked structure and the second boron containing layer along the side surface of the second stacked structure, separated from the first metal oxide layer, and containing the predetermined metal element and oxygen (O), wherein each of the first and second stacked structures includes a structure in which a basic portion, a lower portion provided on a lower layer side of the basic portion and having conductivity, and an upper portion provided on an upper layer side of the basic portion and having conductivity are stacked in a first direction, and the basic portion includes a structure in which a first magnetic layer having a variable magnetization direction, a second magnetic layer having a fixed magnetization direction, and a nonmagnetic layer provided between the first magnetic layer and the second magnetic layer are stacked in the first direction.

Hereinafter, embodiments will be described with reference to the drawings.

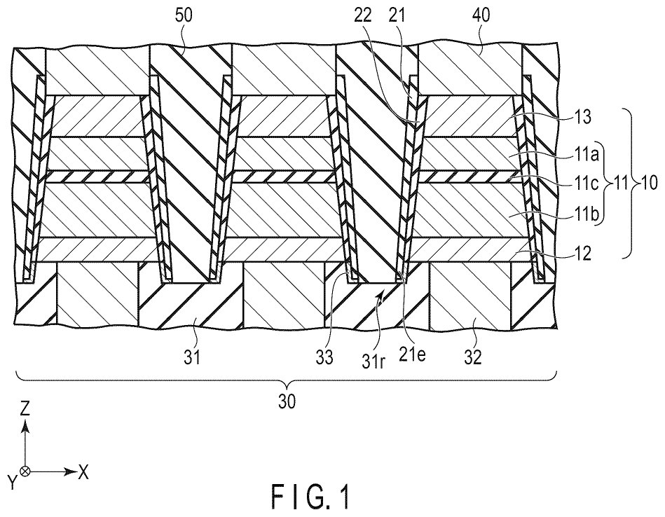

FIG. 1 is a cross-sectional view schematically illustrating a configuration of a magnetic memory device according to an embodiment.

The magnetic memory device according to the present embodiment is provided on a semiconductor substrate (not illustrated) and includes a plurality of stacked structures 10, a plurality of boron containing layers 21, a plurality of metal oxide layers 22, a lower structure 30, a plurality of upper wiring lines 40, and an upper insulating layer 50.

The stacked structures 10 are provided on the lower structure 30 and arranged in an array in an X direction and a Y direction. Each of the stacked structures 10 has a structure in which a plurality of layers are stacked in a Z direction. The X direction, the Y direction, and the Z direction are directions intersecting each other. Specifically, the X direction, the Y direction, and the Z direction are orthogonal to each other.

Each of the stacked structures 10 functions as a magnetic tunnel junction (MTJ) element which is a magnetoresistance effect element. Each stacked structure 10 includes a basic portion 11, a lower portion 12, and an upper portion 13, and includes a structure in which the basic portion 11, the lower portion 12, and the upper portion 13 are stacked in the Z direction.

The basic portion 11 includes a storage layer (first magnetic layer) 11a, a reference layer (second magnetic layer) 11b, and a tunnel barrier layer (nonmagnetic layer) 11c, and includes a structure in which the storage layer 11a, the reference layer 11b, and the tunnel barrier layer 11c are stacked in the Z direction. The basic portion 11 functions as a basic portion of the magnetoresistance effect element.

The storage layer 11a is a ferromagnetic layer having a variable magnetization direction. The variable magnetization direction indicates that a magnetization direction changes with respect to a predetermined write current. The storage layer 11a contains at least one element selected from iron (Fe) and cobalt (Co). Specifically, the storage layer 11a is formed of a FeCoB layer containing iron (Fe), cobalt (Co), and boron (B).

The reference layer 11b is a ferromagnetic layer having a fixed magnetization direction, and includes a first layer portion and a second layer portion stacked in the Z direction. The fixed magnetization direction indicates that a magnetization direction does not change with respect to a predetermined write current.

The first layer portion is provided on the side close to the tunnel barrier layer 11c and contains at least one element selected from iron (Fe) and cobalt (Co). Specifically, the first layer portion is formed of a FeCoB layer containing iron (Fe), cobalt (Co), and boron (B).

The second layer portion is provided on the side farther from the tunnel barrier layer 11c and contains at least platinum (Pt). Specifically, the second layer portion has a superlattice structure in which a plurality of platinum (Pt) layers and a plurality of cobalt (Co) layers are alternately stacked.

The tunnel barrier layer 11c is an insulating layer provided between the storage layer 11a and the reference layer 11b. Specifically, the tunnel barrier layer 11c is formed of an MgO layer containing magnesium (Mg) and oxygen (O).

In a case where a magnetization direction of the storage layer 11a is parallel to a magnetization direction of the reference layer 11b, the magnetoresistance effect element exhibits a low resistance state with a relatively low resistance. In a case where the magnetization direction of the storage layer 11a is antiparallel to the magnetization direction of the reference layer 11b, the magnetoresistance effect element exhibits a high resistance state with a relatively high resistance. Therefore, the magnetoresistance effect element can store binary data according to its resistance state. The resistance state of the magnetoresistance effect element can be set according to a direction of a current flowing through the magnetoresistance effect element.

Note that the basic portion 11 of the magnetoresistance effect element illustrated in FIG. 1 has a top-free structure in which the storage layer 11a is located on the upper layer side of the reference layer 11b, but the basic portion 11 may have a bottom-free structure in which the storage layer 11a is located on the lower layer side of the reference layer 11b.

The lower portion 12 of the stacked structure 10 is provided on the lower layer side of the basic portion 11, has conductivity, and substantially functions as a bottom electrode of the magnetoresistance effect element. The lower portion 12 is made of a conductive material containing at least one element selected from hafnium (Hf), tungsten (W), titanium (Ti), and aluminum (Al). For example, the lower portion 12 may be formed of any one layer among an Hf layer, a W layer, a Ti layer, and an Al layer, or may be formed of two or more stacked layers among an Hf layer, a W layer, a Ti layer, and an Al layer. In addition, the lower portion 12 may include a layer containing two or more elements among Hf, W, Ti, and Al in the same layer. In the present embodiment, Hf is contained in at least the lowermost part of the lower portion 12.

The upper portion 13 of the stacked structure 10 is provided on the upper layer side of the basic portion 11, has conductivity, and substantially functions as a top electrode of the magnetoresistance effect element. The upper portion 13 contains at least one element selected from hafnium (Hf), tungsten (W), titanium (Ti), aluminum (Al), and ruthenium (Ru). The upper portion 13 includes a hard mask portion and an intermediate portion.

The hard mask portion is a portion of the uppermost layer of the stacked structure 10, and functions as a hard mask when a pattern of the stacked structure 10 is formed. The hard mask portion is made of a conductive material containing at least one element selected from hafnium (Hf), tungsten (W), titanium (Ti), and aluminum (Al). For example, the hard mask portion may be formed of any one layer among an Hf layer, a W layer, a Ti layer, and an Al layer, or may be stacked two or more layers among an Hf layer, a W layer, a Ti layer, and an Al layer. In addition, the hard mask portion may include a layer containing two or more elements among Hf, W, Ti, and Al in the same layer.

The intermediate portion is provided between the basic portion 11 and the hard mask portion and is made of a conductive material. For example, the intermediate portion is formed of a ruthenium (Ru) layer.

The boron containing layers 21 are respectively provided along side surfaces (side walls) of the stacked structures 10, and adjacent boron containing layers 21 provided along side surfaces of adjacent stacked structures 10 are separated from each other. Specifically, the boron containing layer 21 is provided to surround the side surface of each stacked structure 10. The boron containing layer 21 is made of an insulating material containing boron (B). Specifically, the boron containing layer 21 is made of boron nitride (BN) containing boron (B) and nitrogen (N).

The boron containing layer 21 may be provided on the entire side surface of the stacked structure 10 or may be provided on a part of the side surface of the stacked structure 10. However, the boron containing layer 21 is preferably provided to surround at least the entire side surface of the basic portion 11 of the stacked structure 10. In the present embodiment, the boron containing layer 21 is continuously provided on the entire side surface of the stacked structure 10 including the basic portion 11, the lower portion 12, and the upper portion 13. The boron containing layer 21 may further include an extending portion 21e extending to the upper portion of the lower structure 30.

Each of the metal oxide layers 22 is provided between the stacked structure 10 and the boron containing layer 21 along the side surface (side wall) of each of the stacked structures 10, and adjacent metal oxide layers 22 provided along the side surfaces of the adjacent stacked structures 10 are separated from each other. Specifically, the metal oxide layer 22 is provided to surround the side surface of each stacked structure 10 and the side surface of each boron containing layer 21.

The metal oxide layer 22 contains a predetermined metal element and oxygen (O). The bond dissociation energy between the predetermined metal element and oxygen (O) is preferably 500 mJ/mol or more. Specifically, the predetermined metal element is preferably selected from hafnium (Hf), aluminum (Al), scandium (Sc), gadolinium (Gd), tantalum (Ta), and yttrium (Y).

The metal oxide layer 22 may be provided on the entire side surface of the stacked structure 10 or may be provided on a part of the side surface of the stacked structure 10. However, the metal oxide layer 22 is preferably provided to surround at least the entire side surface of the basic portion 11 of the stacked structure 10. In the present embodiment, the metal oxide layer 22 is continuously provided on the entire side surface of the stacked structure 10 including the basic portion 11, the lower portion 12, and the upper portion 13.

The lower structure 30 includes a lower insulating layer 31, a plurality of electrodes 32, and a plurality of metal containing layers 33.

The lower insulating layer 31 functions as an interlayer insulating layer, and is made of a material different from the material of the boron containing layer 21 and the material of the metal oxide layer 22. For example, the lower insulating layer 31 is made of an insulating material such as silicon oxide or silicon nitride.

The electrodes 32 are respectively connected to the lower surfaces of the stacked structures 10. That is, the electrode 32 is connected to the lower surface of the lower portion 12 of each stacked structure 10.

The metal containing layer 33 contains at least one metal element contained in each stacked structure 10. Specifically, the metal containing layer 33 contains at least one element selected from hafnium (Hf), tungsten (W), titanium (Ti), aluminum (Al), iron (Fe), cobalt (Co), platinum (Pt), and ruthenium (Ru). In particular, the metal containing layer 33 contains a relatively large proportion of Hf.

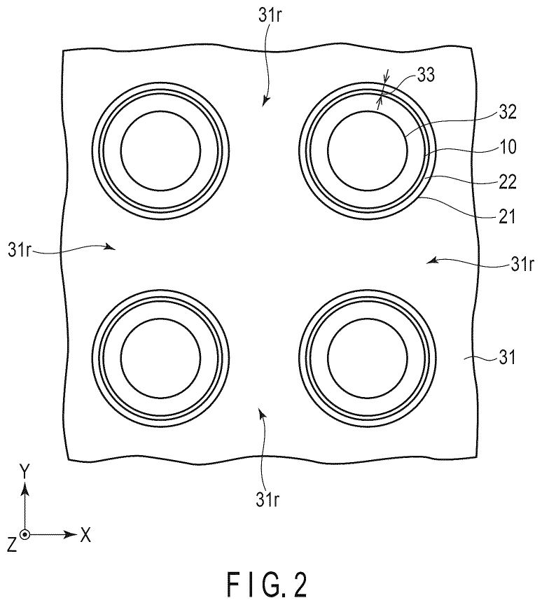

FIG. 2 is a view schematically illustrating a relationship between respective patterns of the stacked structure 10, the boron containing layer 21, the metal oxide layer 22, the lower insulating layer 31, the electrode 32, and the metal containing layer 33 when viewed from the Z direction. Specifically, FIG. 2 is a diagram schematically illustrating a pattern near a boundary between the stacked structure 10 and the lower structure 30.

As illustrated in FIGS. 1 and 2, the lower insulating layer 31 surrounds the side surface of each electrode 32. That is, when viewed from the Z direction, the pattern of the lower insulating layer 31 is provided to surround the circular pattern of each electrode 32. The lower insulating layer 31 has a recess portion 31r, and a pattern of the recess portion 31r surrounds the circular pattern of each stacked structure 10 when viewed from the Z direction.

When viewed from the Z direction, a ring-shaped pattern of the metal oxide layer 22 is provided to surround the circular pattern of the stacked structure 10, and a ring-shaped pattern of the boron containing layer 21 is provided to surround the ring-shaped pattern of the metal oxide layer 22.

The metal containing layer 33 is provided along a side surface of the recess portion 31r of the lower insulating layer 31, and has a ring-shaped pattern along an outer periphery of the pattern of the lower surface of each stacked structure 10 when viewed from the Z direction.

The boron containing layers 21 are provided separately from each other, the metal oxide layers 22 are provided separately from each other, and the metal containing layers 33 are provided separately from each other. Therefore, the boron containing layer 21, the metal oxide layer 22, and the metal containing layer 33 are not provided on a bottom surface of the recess portion 31r of the lower insulating layer 31 except for a portion in the vicinity of the side surface of the recess portion 31r.

As described above, the boron containing layer 21 may include the extending portion 21e that extends to the upper portion of the lower structure 30. In this case, the extending portion 21e is provided along the side surface of the recess portion 31r of the lower insulating layer 31, and is provided to surround the side surface of the metal containing layer 33 along the side surface of the metal containing layer 33.

Each of the upper wiring lines 40 extends in the Y direction, and each of the upper wiring lines 40 is connected to the upper portions 13 of the stacked structures 10 arranged in the Y direction.

The upper insulating layer 50 surrounds a side surface of each of a plurality of structures each including the stacked structure 10, the boron containing layer 21, and the metal oxide layer 22. The upper insulating layer 50 is also provided in a region between the upper wiring lines 40. The upper insulating layer 50 extends to the bottom surface of the recess portion 31r of the lower insulating layer 31. The upper insulating layer 50 functions as an interlayer insulating layer, and is made of a material different from the material of the boron containing layer 21 and the material of the metal oxide layer 22. For example, the upper insulating layer 50 is made of an insulating material such as silicon oxide or silicon nitride.

As described above, in the present embodiment, the boron containing layer 21 is provided along the side surface of the stacked structure 10, and the metal oxide layer 22 is provided between the stacked structure 10 and the boron containing layer 21 along the side surface of the stacked structure 10. As a result, it is possible to obtain a magnetic memory device having excellent characteristics and reliability as described below.

Normally, when the pattern of the stacked structure 10 is formed, a stacked film for the stacked structure 10 is etched through ion beam etching (IBE) or the like by using a hard mask as an etching mask. In this case, a metal containing layer (residue layer) containing a metal element contained in the stacked film is formed in a region between the adjacent stacked structures 10, and thus electrical separation between the adjacent stacked structures 10 may be impaired. That is, electrical separation between adjacent magnetoresistance effect elements may be impaired. In particular, when Hf is contained in the lower portion 12 of the stacked structure 10, a metal containing layer (residue layer) containing Hf is formed, and it is difficult to accurately remove the metal containing layer (residue layer) containing Hf.

In the present embodiment, it is possible to prevent the above problems as described below by providing the boron containing layer 21 along the side surface of the stacked structure 10.

When hafnium (Hf) generated due to etching for forming the pattern of the stacked structure 10 is bonded to oxygen in the interlayer insulating layer or in the atmosphere, hafnium oxide is formed. It is not easy to remove the metal containing layer (residue layer) containing the hafnium oxide through etching.

In the present embodiment, the boron containing layer 21 is formed after the stacked structure 10 is formed. Boron (B) is more easily oxidized than hafnium (Hf). That is, the bond between boron and oxygen is more stable than the bond between hafnium and oxygen. Therefore, providing the boron containing layer 21 bonds oxygen of the hafnium oxide in the metal containing layer (residue layer) to boron (B), and reduces the hafnium oxide to hafnium (Hf). Since hafnium (Hf) is easier to etch than hafnium oxide, the metal containing layer (residue layer) can be easily removed.

However, if the boron containing layer 21 is directly formed on the side surface of the stacked structure 10, the characteristics and reliability of the stacked structure 10, that is, the characteristics and reliability of the magnetoresistance effect element may be adversely affected. For example, the stacked structure 10 is insufficiently protected, and the characteristics and reliability of the magnetoresistance effect element may deteriorate. In addition, the characteristics and reliability of the magnetoresistance effect element may deteriorate due to the presence of the boron containing layer 21.

In the present embodiment, since the metal oxide layer 22 is provided between the stacked structure 10 and the boron containing layer 21, it is possible to prevent the above problems.

Therefore, in the present embodiment, it is possible to electrically accurately separate adjacent magnetoresistance effect elements from each other, to curb deterioration in characteristics and reliability of the magnetoresistance effect elements, and to obtain a magnetic memory device having excellent characteristics and reliability.

Next, a method of manufacturing the magnetic memory device according to the present embodiment will be described with reference to FIGS. 3 to 6 and FIG. 1.

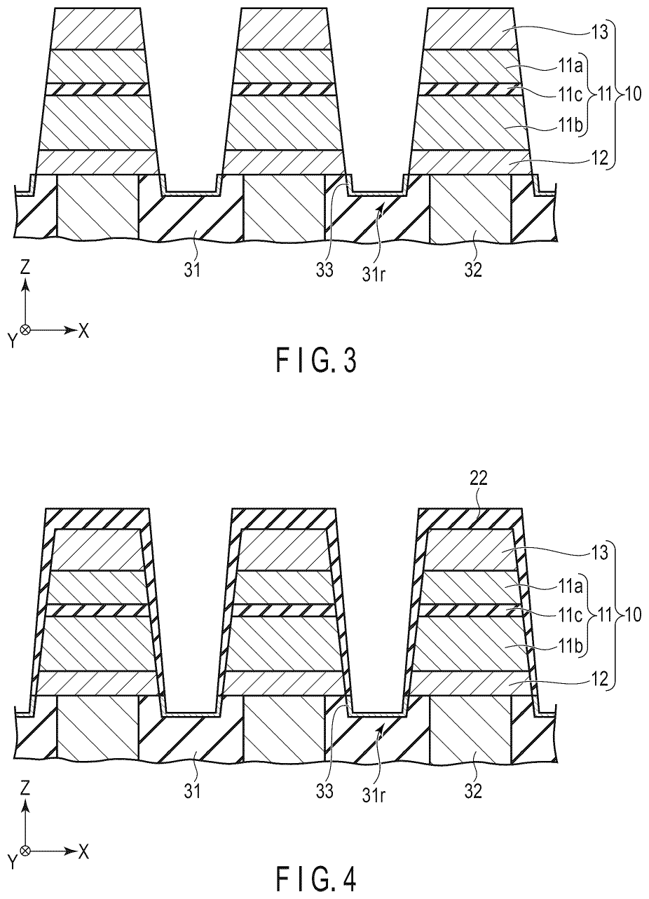

First, as illustrated in FIG. 3, a stacked film for the stacked structure 10 is formed on a structure including the lower insulating layer 31 and the electrode 32. Subsequently, a hard mask layer included in the uppermost layer of the stacked film is patterned to form a hard mask pattern. Further, etching is performed through IBE by using the hard mask pattern as a mask. As described above, the stacked structure 10 including the basic portion 11 (the storage layer 11a, the reference layer 11b, and the tunnel barrier layer 11c), the lower portion 12, and the upper portion 13 is formed. In this etching process, overetching is performed to physically and reliably separate adjacent stacked structures 10. As a result, a part of the lower insulating layer 31 is etched to form the recess portion 31r. In addition, the metal containing layer (residue layer) 33 containing the metal element contained in the stacked structure 10 is formed on the bottom surface and the side surface of the recess portion 31r. The metal containing layer (residue layer) 33 contains hafnium oxide and the like.

Next, as illustrated in FIG. 4, the metal oxide layer 22 is formed to cover the structure obtained in the step in FIG. 3. In this case, it is preferable not to form the metal oxide layer 22 on the bottom surface of the recess portion 31r of the lower insulating layer 31. For example, the metal oxide layer 22 is formed under such a condition that the metal oxide layer 22 is not deposited on the bottom surface of the recess portion 31r. Alternatively, in a case where the metal oxide layer 22 is also deposited on the bottom surface of the recess portion 31r, the metal oxide layer 22 deposited on the bottom surface of the recess portion 31r is removed through anisotropic etching such as IBE or reactive ion etching (RIE).

Next, as illustrated in FIG. 5, the boron containing layer 21 is formed to cover the structure obtained in the step in FIG. 4. Specifically, a boron nitride (BN) layer is formed as the boron containing layer 21.

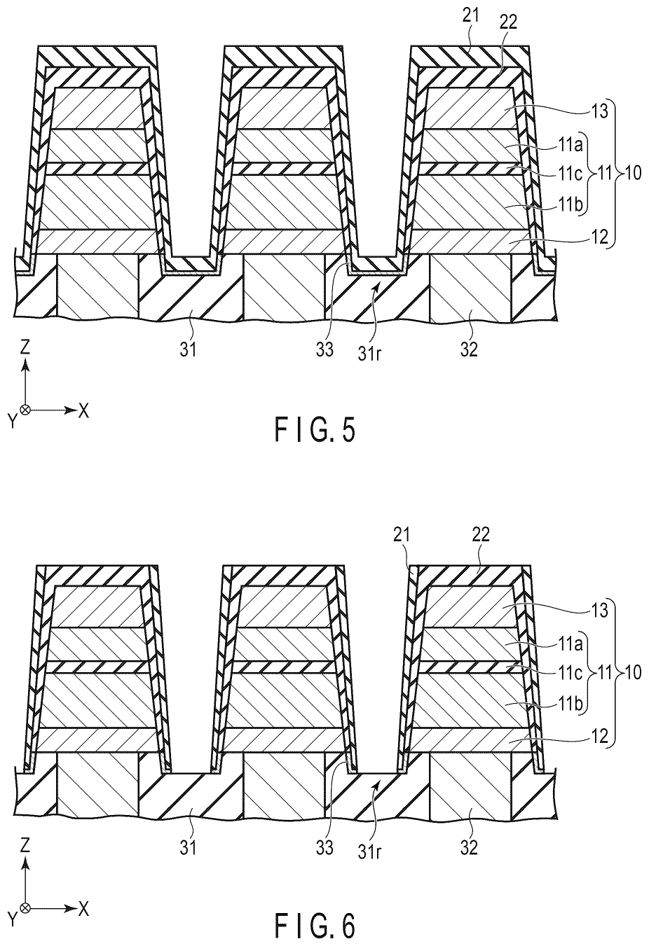

Next, as illustrated in FIG. 6, the boron containing layer 21 is subjected to anisotropic etching through RIE. As an etching gas, a gas containing chlorine (Cl) (for example, a Cl₂ gas) is used. Through this anisotropic etching, the boron containing layer 21 formed on the upper surface of the stacked structure 10 and the bottom surface of the recess portion 31r of the lower insulating layer 31 is removed, and only the boron containing layer 21 formed on the side surface of the stacked structure 10 remains. In addition, the metal containing layer 33 formed on the bottom surface of the recess portion 31r is also removed through the anisotropic etching.

As described above, the metal containing layer (residue layer) 33 contains hafnium oxide and the like. Boron (B) is more easily oxidized than hafnium (Hf), and the bond between boron and oxygen is more stable than the bond between hafnium and oxygen. Thus, forming the boron containing layer 21 before performing the anisotropic etching described above bonds oxygen in the hafnium oxide to boron to generate hafnium. As a result, the metal containing layer (residue layer) 33 containing hafnium can be easily removed.

As an etching gas, a gas containing chlorine (Cl) and boron (B) (for example, a mixed gas of a Cl₂ gas and a BCl₃ gas) may be used. As described above, it is possible to further promote the removal of the metal containing layer (residue layer) 33 containing hafnium by adding the gas containing boron (B).

Thereafter, a structure as illustrated in FIG. 1 is obtained by removing the metal oxide layer 22 on the stacked structure 10 and forming the wiring line 40 and the upper insulating layer 50. Even if the metal oxide layer 22 and the boron containing layer 21 remain on the upper surface or the like of the stacked structure 10 after the step in FIG. 6, the metal oxide layer 22 and the boron containing layer 21 remaining on the upper surface or the like of the stacked structure 10 can be removed when the pattern of the wiring line 40 is formed.

As described above, according to the above-described manufacturing method, by forming the boron containing layer 21, the metal containing layer (residue layer) 33 can be easily removed, and adjacent magnetoresistance effect elements (adjacent stacked structures 10) can be electrically accurately separated. In addition, the stacked structure 10 can be effectively protected by forming the metal oxide layer 22. Therefore, it is possible to form a magnetic memory device having excellent characteristics and reliability.

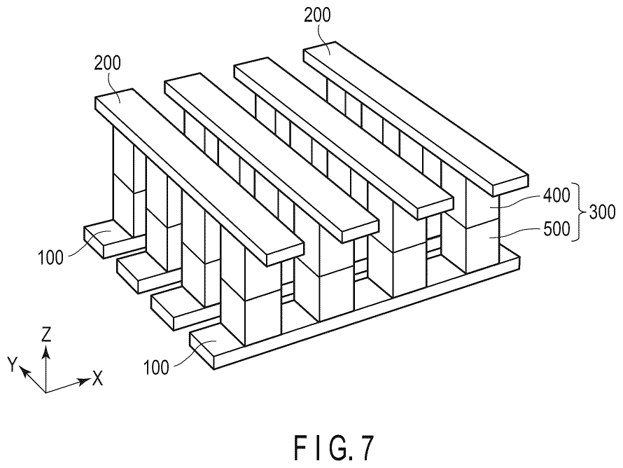

Next, an application example of the magnetic memory device of the present embodiment will be described. FIG. 7 is a perspective view schematically illustrating a configuration of an application example of the magnetic memory device of the present embodiment.

A memory device illustrated in FIG. 7 includes a plurality of wiring lines 100, a plurality of wiring lines 200, and a plurality of memory cells 300 provided between the wiring lines 100 and the wiring lines 200.

Each of the wiring lines 100 extends in the X direction, and each of the wiring lines 200 extends in the Y direction. One of the wiring line 100 and the wiring line 200 corresponds to a word line, and the other of the wiring line 100 and the wiring line 200 corresponds to a bit line. In addition, the wiring line 200 corresponds to the wiring line 40 of the above-described embodiment.

Each of the memory cells 300 includes a magnetoresistance effect element 400 and a selector (switching element) 500, and has a structure in which the magnetoresistance effect element 400 and the selector 500 are stacked in the Z direction. That is, each memory cell 300 has a structure in which the magnetoresistance effect element 400 and the selector 500 are connected in series. The magnetoresistance effect element 400 and the selector 500 are connected via the electrode 32 of the above embodiment.

A basic structure of the magnetoresistance effect element 400 corresponds to the structure (the structure including the stacked structure 10, the boron containing layer 21, the metal oxide layer 22, and the like) described in the above embodiment. The selector 500 is a two-terminal switching element, and has a characteristic of transitioning from an off state to an on state when a voltage applied between two terminals reaches a threshold voltage.

When a voltage is applied between the wiring line 100 and the wiring line 200 and a voltage applied to the selector 500 is equal to or higher than the threshold voltage, the selector 500 transitions from an off state to an on state. As a result, a current flows through the magnetoresistance effect element 400 connected in series to the selector 500, and writing or reading can be performed on the magnetoresistance effect element 400.

By applying the magnetic memory device of the present embodiment to a memory device as illustrated in FIG. 7, it is possible to obtain a memory device having excellent characteristics and reliability.

Note that the memory device illustrated in FIG. 7 has a structure in which the magnetoresistance effect element 400 is located on the upper layer side of the selector 500, but may have a structure in which the magnetoresistance effect element 400 is located on the lower layer side of the selector 500.

While certain embodiments have been described, these embodiments have been presented by way of example only, and are not intended to limit the scope of the inventions. Indeed, the novel devises and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a lower structure;
a first stacked structure provided on the lower structure;
a second stacked structure provided on the lower structure and being adjacent to the first stacked structure;
a first boron containing layer provided along a side surface of the first stacked structure and containing boron (B);
a second boron containing layer provided along a side surface of the second stacked structure, separated from the first boron containing layer, and containing boron (B);
a first metal oxide layer provided between the first stacked structure and the first boron containing layer along the side surface of the first stacked structure and containing a predetermined metal element and oxygen (O); and
a second metal oxide layer provided between the second stacked structure and the second boron containing layer along the side surface of the second stacked structure, separated from the first metal oxide layer, and containing the predetermined metal element and oxygen (O),
wherein
each of the first and second stacked structures includes a structure in which a basic portion, a lower portion provided on a lower layer side of the basic portion and having conductivity, and an upper portion provided on an upper layer side of the basic portion and having conductivity are stacked in a first direction, and
the basic portion includes a structure in which a first magnetic layer having a variable magnetization direction, a second magnetic layer having a fixed magnetization direction, and a nonmagnetic layer provided between the first magnetic layer and the second magnetic layer are stacked in the first direction.

2. The device according to claim 1, wherein
the first and second boron containing layers further contain nitrogen (N).

3. The device according to claim 1, wherein
a bond dissociation energy between the predetermined metal element and oxygen (O) is mJ/mol or more.

4. The device according to claim 1, wherein
the predetermined metal element is selected from hafnium (Hf), aluminum (Al), scandium (Sc), gadolinium (Gd), tantalum (Ta), and yttrium (Y).

5. The device according to claim 1, wherein
the first magnetic layer contains at least one element selected from iron (Fe) and cobalt (Co).

6. The device according to claim 1, wherein
the second magnetic layer contains at least one element selected from iron (Fe) and cobalt (Co).

7. The device according to claim 6, wherein
the second magnetic layer further contains platinum (Pt).

8. The device according to claim 1, wherein
the nonmagnetic layer contains magnesium (Mg) and oxygen (O).

9. The device according to claim 1, wherein
the lower portion contains at least one element selected from hafnium (Hf), tungsten (W), titanium (Ti), and aluminum (Al).

10. The device according to claim 1, wherein
the upper portion contains at least one element selected from hafnium (Hf), tungsten (W), titanium (Ti), aluminum (Al), and ruthenium (Ru).

11. The device according to claim 1, wherein
the lower structure includes a lower insulating layer having a recess portion, and
when viewed from the first direction, a pattern of the recess portion surrounds a pattern of the first stacked structure and a pattern of the second stacked structure.

12. The device according to claim 11, wherein
the lower structure further includes
a first metal containing layer provided along a side surface of the recess portion, having a pattern along an outer periphery of a pattern of a lower surface of the first stacked structure when viewed from the first direction, and containing at least one metal element contained in the first stacked structure; and
a second metal containing layer provided along a side surface of the recess portion, having a pattern along an outer periphery of a pattern of a lower surface of the second stacked structure when viewed from the first direction, and containing at least one metal element contained in the second stacked structure.

13. The device according to claim 12, wherein
the first boron containing layer includes a first extending portion provided along a side surface of the first metal containing layer, and
the second boron containing layer includes a second extending portion provided along a side surface of the second metal containing layer.

14. The device according to claim 12, wherein
each of the first and second metal containing layers contains at least one element selected from hafnium (Hf), tungsten (W), titanium (Ti), aluminum (Al), iron (Fe), cobalt (Co), platinum (Pt), and ruthenium (Ru).

15. The device according to claim 11, wherein
the lower structure further includes a first electrode connected to a lower surface of the first stacked structure and a second electrode connected to a lower surface of the second stacked structure, and
the lower insulating layer surrounds a side surface of the first electrode and a side surface of the second electrode.

16. The device according to claim 1, further comprising:
an upper insulating layer surrounding a side surface of a structure including the first stacked structure, the first boron containing layer, and the first metal oxide layer, and surrounding a side surface of a structure including the second stacked structure, the second boron containing layer, and the second metal oxide layer.
